(19) United States
(12) Patent Application Publication
(10) Pub. No.: US 2026/0338828 A1
(43) Pub. Date: Oct. 29, 2026

(54) CONNECTING FIXTURE AND ELECTRICAL TESTING DEVICE

(71) Applicant: Fulian Precision electronics (Tianjin) Co., LTD., Tianjin (CN)

(72) Inventors: WEI-MING LEE, New Taipei (TW); CHI-WEN CHEN, New Taipei (TW)

(21) Appl. No.: 19/716,435

(22) Filed: Jun. 23, 2026

(30) Foreign Application Priority Data
Jan. 27, 2025 (CN) 202610112808.1

(51) Int. Cl. G01R 1/04; G06F 1/28; H01R 25/00; H01R 25/16

(52) U.S. Cl. CPC G01R 1/0416; G06F 1/28; H01R 25/006; H01R 25/165; H01R 2201/20

(57) ABSTRACT

A connecting fixture and an electrical testing device are provided. The connecting fixture includes a housing, a first conductive structure disposed on the first side wall of the housing, a second conductive structure disposed on the second side wall of the housing, and bus connector disposed at an end of the housing and electrically connected to both the first conductive bar and the second conductive bar. The first conductive structure includes a first conductive bar and a plurality of first terminals. Each first terminal is electrically connected to the first conductive bar. The second conductive structure includes a second conductive bar and a plurality of second terminals. Each second terminal is electrically connected to the second conductive bar. The first terminal and a corresponding second terminal are configured to connect two poles of a load, respectively.

### CROSS-REFERENCE TO RELATED APPLICATION(S)

The present application claims the benefit and priority to Chinese Patent Application Serial No. 202610112808.1, filed on Jan. 27, 2026, in China National Intellectual Property Administration, and the content of which is hereby fully incorporated by reference into the present application.

### FIELD

The subject matter herein generally relates to computing system technology, especially to a connecting fixture and an electrical testing device.

### BACKGROUND

In high-power data center, precise measurement of current or voltage between racks and servers is required to ensure system stability and power efficiency. Traditional measurement methods rely on manual handheld instruments, such as multimeters or clamp meters. These methods are not only cumbersome and inefficient in operation but also prone to human factors which may compromise measurement accuracy, resulting in low efficiency, imprecise measurements, reduced operational productivity, and lower yield rates. Furthermore, the manual measurement method is usually inconvenient to use and cannot quickly detect the large number of densely distributed interfaces or ports of the server.

Improvements in the art are desired.

### BRIEF DESCRIPTION OF THE DRAWINGS

FIG. 1 is a diagrammatic view of an electrical testing system according to an embodiment of the present disclosure.

FIG. 2A is a diagrammatic view of a connecting fixture and an electrical testing device of the testing system shown in FIG. 1, before assembly.

FIG. 2B is a diagrammatic view of the connecting fixture and the electrical testing device of FIG. 2A, after assembly.

FIG. 3 is a diagrammatic view of a connecting fixture of the electrical testing system shown in FIG. 1.

FIG. 4 is a diagrammatic view showing the connecting fixture viewed from another perspective of FIG. 3.

FIG. 5 is a top view of the connecting fixture in FIG. 3, after a top plate is removed.

FIG. 6 is a diagrammatic view showing a first terminal of the connecting fixture of FIG. 3.

FIG. 7 is a cross-sectional view of an embodiment along VII-VII of the first terminal shown in FIG. 6.

FIG. 8 is a diagrammatic view showing a bus connector of the connecting fixture of FIG. 5.

FIG. 9 is a top view of the bus connector of FIG. 8.

FIG. 10 is a diagrammatic view showing an output connector of the connecting fixture of FIG. 3.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Implementations of the present disclosure will now be described, by way of embodiments, with reference to the above figures. The embodiments are obviously a portion but not all of the embodiments of the present disclosure.

When a component is fixed to another component, the two components may be directly fixed to each other or indirectly fixed to each other or through an intermediate medium. When a component is located on another component, the component may be directly located on the another component, or an intermediate medium may exist therebetween.

Unless otherwise defined, the technical terms used in the present disclosure have the same meanings as those commonly understood by those skilled in the art. The terms used in the present disclosure are for describing specific embodiments but not intended to limit the scope of present disclosure.

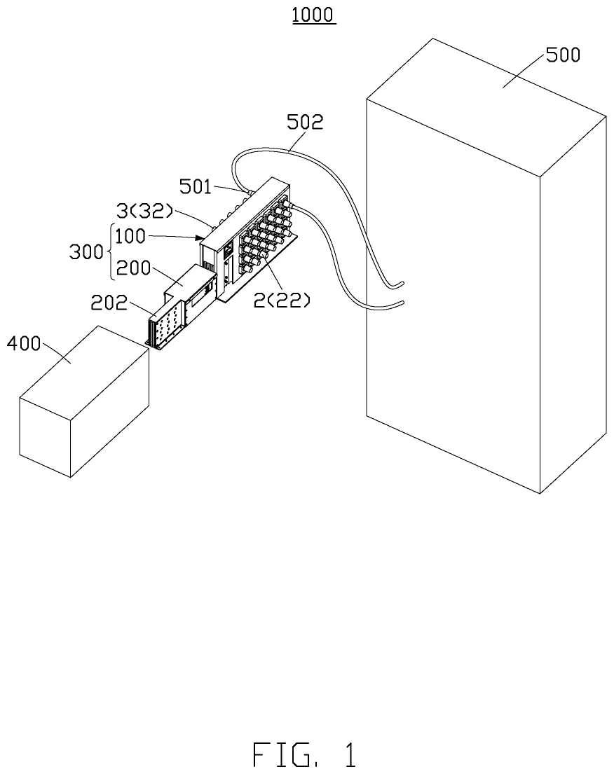

Referring to FIGS. 1 to 3, an electrical testing system 1000 is provided according to an embodiment of the present disclosure. The electrical testing system 1000 includes an electrical testing device 300, a power cabinet 400 and a plurality of loads 500. For example, the loads 500 may be servers. The electrical testing device 300 includes a connecting fixture 100 and an electrical testing fixture 200 detachably and electrically connected to the connecting fixture 100.

In some embodiments, the electrical testing fixture 200 includes a first connector 201 and a second connector 202. The first connector 201 is detachably and electrically connected to the connecting fixture 100, and the second connector 202 is detachably and electrically connected to the power cabinet 400. The connecting fixture 100 is further detachably and electrically connected to the plurality of loads 500. The electrical testing device 300 is configured to detect at least one of a current and a voltage between the power cabinet 400 and each load 500.

Referring to FIGS. 1 to 5, the connecting fixture 100 includes a housing 1, a first conductive structure 2, a second conductive structure 3, and a bus connector 4. The housing 1 includes a first side wall 11 and a second side wall 12 disposed opposite to the first side wall 11. The first side wall 11 and the second side wall 12 cooperatively define a cavity 13. The first conductive structure 2 includes a first conductive bar 21 and a plurality of first terminals 22. The first conductive bar 21 is disposed in the cavity 13. The first terminals 22 are disposed on a side of the first side wall 12 away from the cavity 13. Each first terminal 22 extends through the first side wall 11 and is electrically connected to the first conductive bar 21. The second conductive structure 3 includes a second conductive bar 31 and a plurality of second terminals 32. The second conductive bar 31 is disposed in the cavity 13. The second terminals 32 are disposed on a side of the second side wall 12 away from the cavity 13. Each second terminal 32 extends through the second side wall 12 and is electrically connected to the second conductive bar 31. Each first terminal 22 and a corresponding second terminal 32 are configured to connect two poles of the load 500, respectively. The two poles of the load 500 serve as a positive terminal and a negative terminal, respectively. In an embodiment, the first terminals 22 are negative terminals for connecting negative poles of the loads 500, and the second terminals 32 are positive terminals for connecting positive poles of the loads 500. The bus connector 4 is disposed at one end of the housing 1 and electrically connected to both the first conductive bar 21 and the second conductive bar 31. The bus connector 4 is further detachably and electrically connected to the electrical testing fixture 200.

The housing 1 further includes a first end wall 14, a second end wall 15, a bottom plate 16, and a top plate 17. The first end wall 14 is connected to an end of the first side wall 11 and the second side wall 12, the second end wall 15 is connected to an end the first side wall 11 and the second side wall 12 away from the first end wall 14. That is, the first end wall 14 and the second end wall 15 are connected to the front end and the rear end of the housing 1, respectively. The bottom plate 16 is connected to the lower end of the first side wall 11 and the second side wall 12. The top plate 17 is connected to the upper end of the first side wall 11 and the second side wall 12. Thus, the first side wall 11, the second side wall 12, the first end wall 14, the second end wall 15, the bottom plate 16, and the top plate 17 cooperatively form the cavity 13. The bus connector 4 extends through the first end wall 14. The first end wall 14 defines an opening 18. The bus connector 4 includes a plurality of sockets exposed from the opening 18. The sockets are used for connecting with the connector of the electrical testing fixture 200.

In some embodiments, the housing 1 is made of an insulating material.

In some embodiments, the housing 1 is substantially rectangular. The area of each of the first side wall 11 and the second side wall 12 is larger than the area of each of the first end wall 14 and the second end wall 15. Therefore, the first side wall 11 can provide a larger mounting area for mounting the first conductive structures 2, and the second side wall 12 can provide a larger mounting area for mounting the second conductive structures 3, so that more terminals can be arranged to connect a greater number of loads 500.

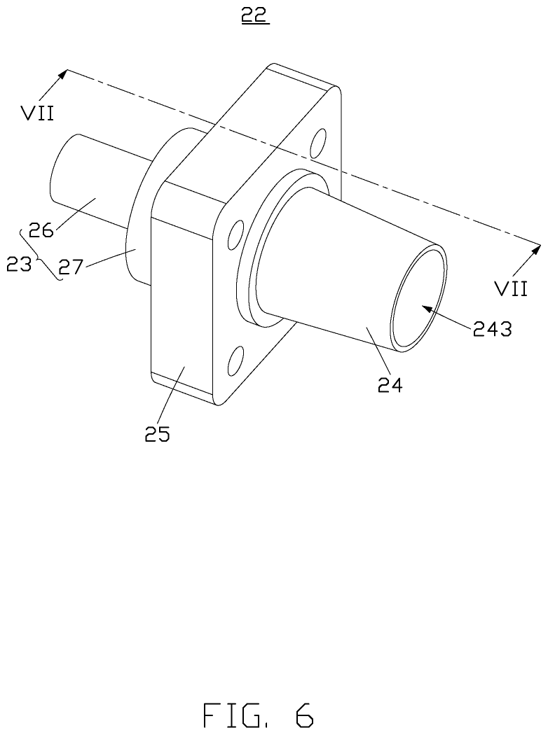

Referring to FIGS. 1, 5, and 6, each first terminal 22 includes a first end 23, a second end 24, and a fixing portion 25. The first end 23 and the second end 24 are connected to two opposite ends of the fixed portion 15, respectively. The first end 23 extends through the first side wall 11 into the cavity 13 and is electrically connected to the first conductive bar 21. The fixing portion 25 is disposed on the outer side of the first side wall 11 and fixed thereto. The second end 24 is disposed on the outer side of the first side wall 11 and configured to connect the corresponding load 500.

The first conductive bar 21 is spaced apart from and substantially parallel to the first side wall 11. In some embodiments, the first end 23 includes a connecting rod 26 electrically connected to the second end 24 and a limiting portion 27 sleeved on a segment close to the fixing portion 25 of the connecting rod 26. The outer diameter of the connecting rod 26 is smaller than the outer diameter of the limiting portion 27. The connecting rod 26 extends through the first conductive bar 21, and the limiting portion 27 is disposed between the first conductive bar 21 and the first side wall 11 to separate them from each other. All the first terminals 22 have uniform overall dimensions, and all the limiting portions 27 have uniform width. Thus, the first conductive bar 21 is kept substantially parallel to and spaced apart from the first side wall 11.

In some embodiments, the connecting rod 26 is fastened by a nut after penetrating through the first conductive bar 21.

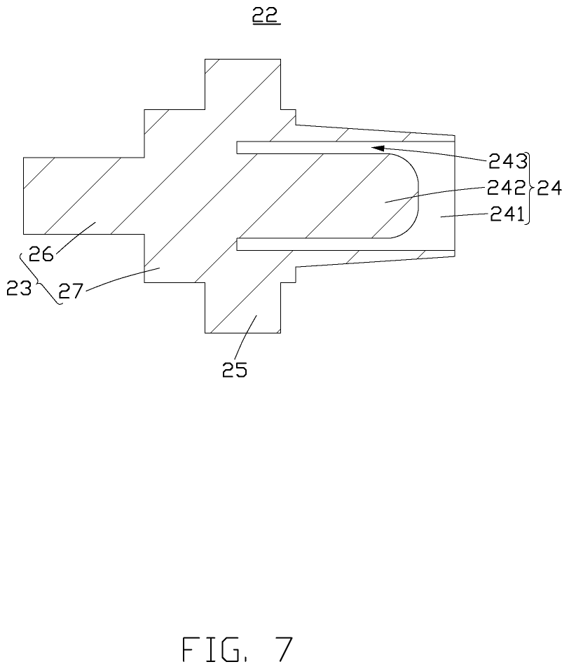

Referring to FIGS. 1, 5 to 7, the second end 24 includes an insulating sheath 241 and a contact pin 242 disposed inside the insulating sheath 242. The contact pin 242 is electrically connected to the connecting rod 26. A slot 243 is formed between the insulating sheath 241 and the contact pin 242. The second end 24 can be plugged and mated with a terminal on the load 500.

In some embodiments, the first terminal 22 is a female Rhino terminal. A terminal 501 which is a male Rhino terminal can be connected to an interface or port of the load 500 through a wire 502, enabling quick plugging and unplugging to improve testing efficiency. The terminal 501 is connected to the load 500 through a retractable wire 502, which facilitates wiring layout, saves space and prevents wire tangling.

In some embodiments, the limiting portion 27, the fixing portion 25, and the insulating sheath 241 are all made of insulating materials.

In some embodiments, the limiting portion 27, the fixing portion 25, and the insulating sheath 241 are formed as an integral structure.

In some embodiments, the first conductive bar 21, the connecting rod 26, and the contact pin 242 are all made of copper.

In some embodiments, the housing 1 further includes a plurality of fixing plates 18. Each of the first conductive bar 21 and the second conductive bar 31 is connected to the bottom plate 16 through at least one fixing plate 8 to enhance structural stability.

In some embodiments, the fixing plate 8 is insulating plate.

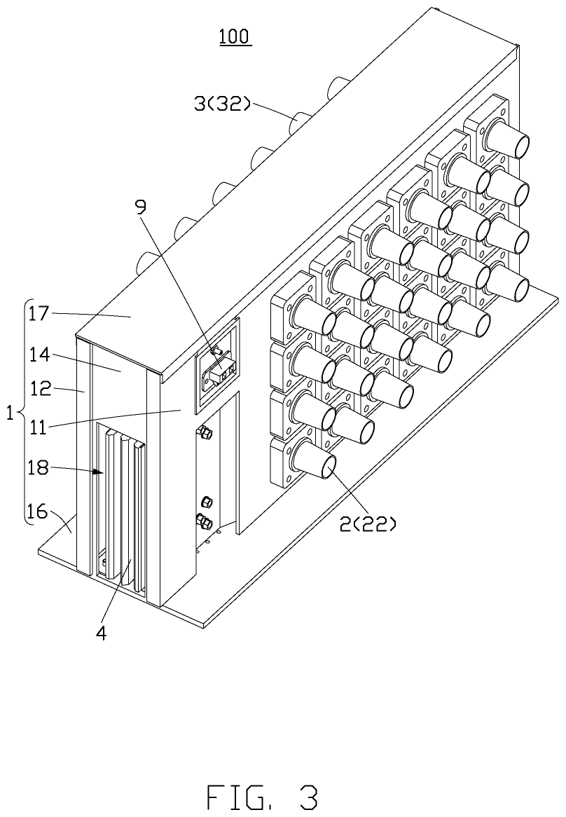

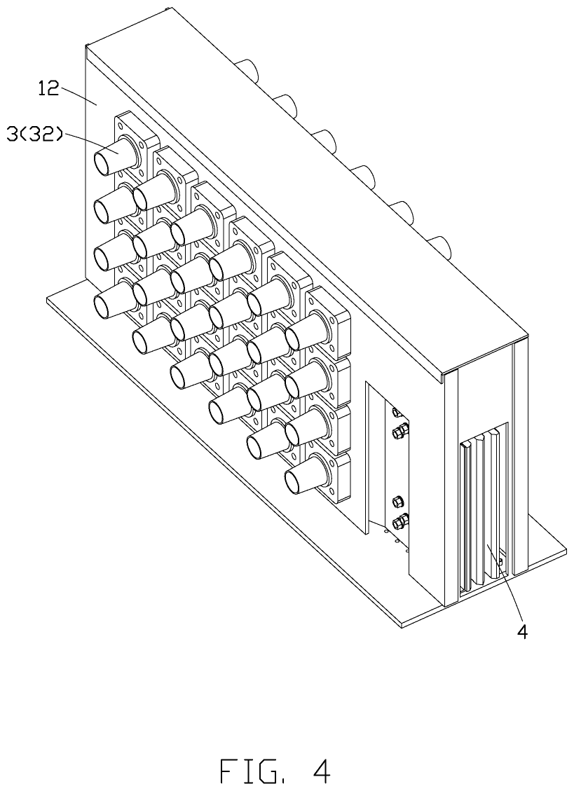

Referring to FIGS. 3 and 4, the structure of each second terminal 32 is substantially the same as the structure of each first terminal 22, and details thereof will not be repeated herein.

Referring to FIGS. 3 and 4, the plurality of first terminals 22 is arranged in an array, and the plurality of second terminals 32 is also arranged in an array. The number of the first terminals 22 is equal to the number of the second terminals 32. Each first terminals 22 and a corresponding second terminal 32 form a terminal group. Multiple terminal groups can be arranged according to the number of the loads 500 to be connected, so as to realize convenient and rapid testing for a large number of densely distributed server ports.

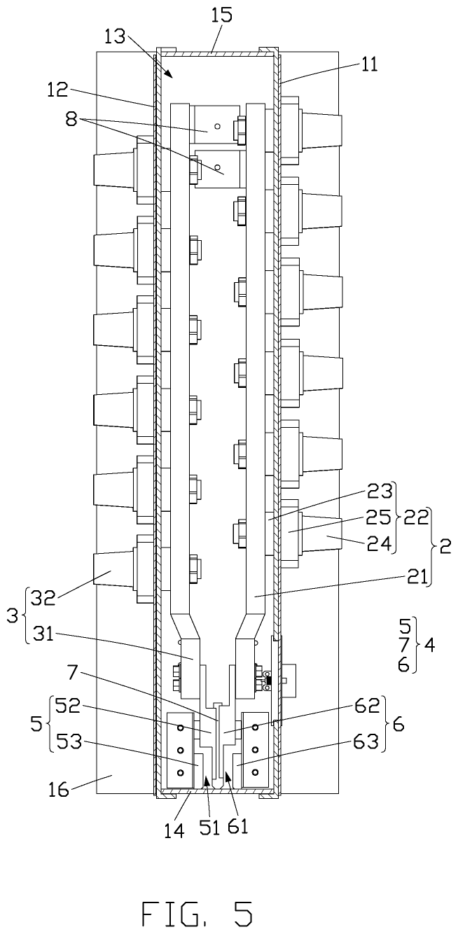

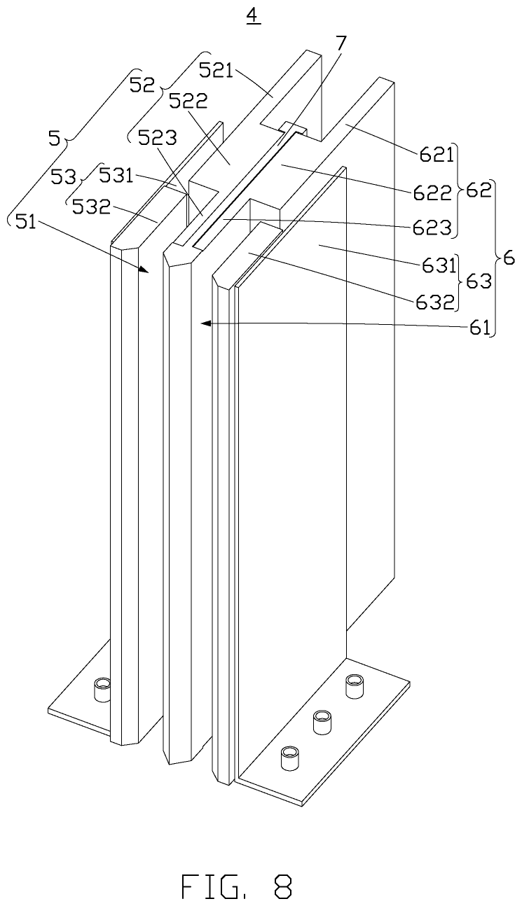

Referring to FIGS. 5 and 8, the bus connector 4 includes a first bus bar 5, a second bus bar 6, and an insulating sheet 7. The first bus bar 5 and the second bus bar 6 are arranged side by side, and the insulating sheet 7 is disposed between the first bus bar 5 and the second bus bar 6. The first bus bar 5 is electrically connected to the first conductive bar 21. The first bus bar 5 includes a first socket 51 at an end of the first bus bar 5 away from the first conductive bar 21. The second bus bar 6 is electrically connected to the second conductive bar 31. The second bus bar 6 includes a second socket 61 at an end of the second bus bar 6 away from the second conductive bar 31. The first connector 201 of the electrical testing fixture 200 has a positive pole and a negative pole. One of the negative pole and the positive pole is inserted into the first socket 51 of the first bus bar 5, and the other one of the negative pole and the positive pole is inserted into the second socket 61 of the second bus bar 6. The first bus bar 5 realizes electrical connection between the multiple first terminals 22 and one pole (positive pole or negative pole) of the electrical testing fixture 200. The second bus bar 6 realizes electrical connection between the multiple second terminals 32 and another pole (positive pole or negative pole) of the electrical testing fixture 200. The structure is simplified and plugging operation is convenient.

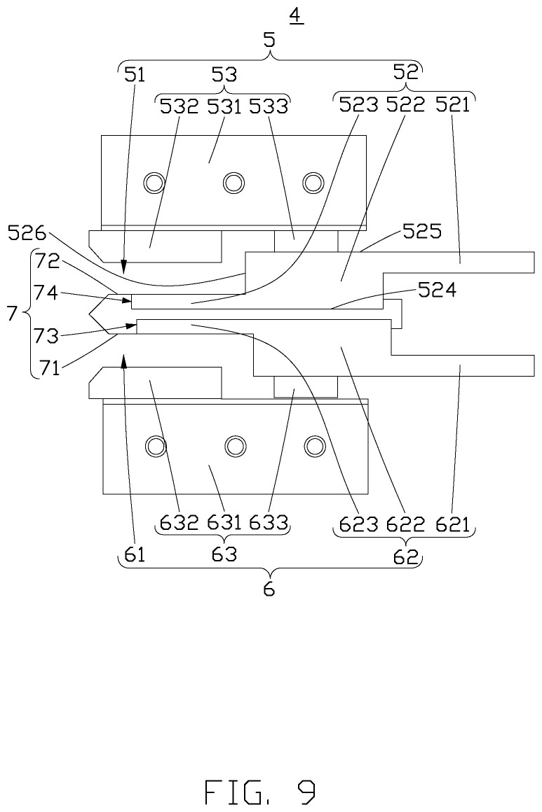

Referring to FIGS. 1, 2A, 2B, 5, 8, and 9, the connecting fixture 100 includes one bus connector 4. The number of each of the first bus bar 5 and the second bus bar 6 is one. Each of the first socket 51 and the second socket 61 extends along a vertical direction Z. The bus connector 4 can be connected to one or more first connectors 201. In some embodiments, the electrical testing fixture 200 includes a plurality of first connectors 201 arranged in a column along the vertical direction Z, and all of the first connectors 201 can be simultaneously plugged into the first socket 51 and the second socket 61 of the bus connector 4. The heights of the first bus bar 5 and the second bus bar 6 can be designed according to the number of the first connectors 201. In the electrical testing fixture 200, one first connector 201 corresponds to 1RU, and three first connectors 201 correspond to 3RU. The bus connector 4 is suitable for the electrical testing fixture 200 with 3UR.

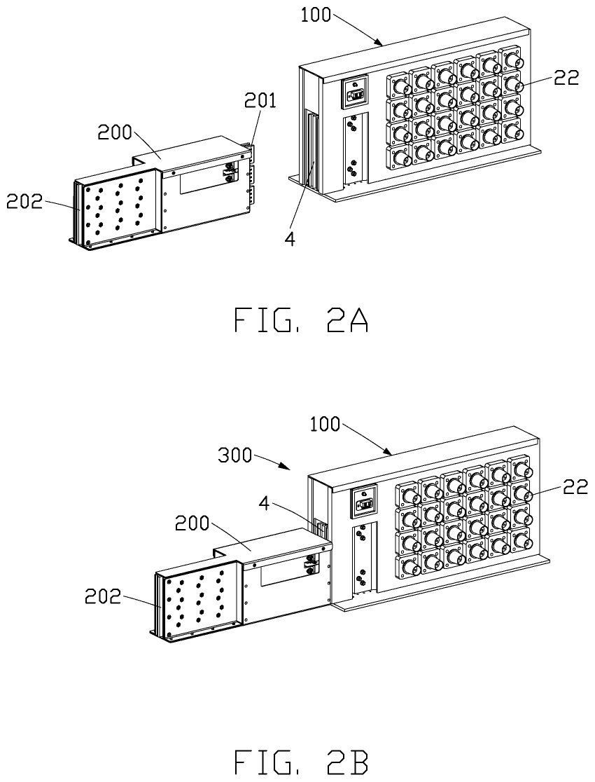

Referring to FIGS. 2A, 2B, 5, 8 and 9, the first bus bar 5 includes a first bus board 52 and a first adapter board 53. The first bus board 52 is electrically connected to the first conductive bar 21. The first adapter board 53 is connected to the first bus board 52. The first adapter board 53 and the first bus board 52 cooperatively form the first socket 51. The second bus bar 6 includes a second bus board 62 and a second adapter board 63. The second bus board 62 is electrically connected to the second conductive bar 31. The second adapter board 63 is connected to the second bus board 62. The second adapter board 63 and the second bus board 62 cooperatively form the second socket 61. Both the first bus bar 5 and the second bus bar 6 are made of metal materials. The first bus board 52 and the first adapter board 53 are disposed on two opposites sides of the first socket 51. One pole of the first connector 201 can be clamped by the first bus board 52 and the first adapter board 53. Similarly, the second bus board 62 and the second adapter board 63 are disposed on two opposites sides of the second socket 61. Another pole of the first connector 201 can be clamped by the second bus board 62 and the second adapter board 63. Thereby, the plugging stability is improved and the electrical contact area is enlarged.

In some embodiments, the first bus board 52 includes a first bus portion 521, a first connecting portion 522, and a second bus portion 523 connected to each other in sequence. An end of the first bus portion 521 away from the first connecting portion 522 is connected to the first conductive bar 21. The first adapter board 53 includes a first connecting piece 531 disposed on the housing 1 and a first extending piece 532 disposed on the first connecting piece 531. An end of the first connecting piece 531 away from the first extending piece 532 is connected to the first connecting portion 522. The first extending piece 532 is disposed opposite to the second bus portion 523 to form the first socket 51.

In some embodiments, the first bus portion 521 is detachably connected to the first conductive bar 21 by bolts.

In some embodiments, the first bus board 52 includes a first surface 524 and a second surface 525 opposite to the first surface 524. The second surface 525 of the first bus portion 521 is recessed toward the first surface 524 to form a first L-shaped step. The first surface 524 of the second bus portion 523 is recessed toward the second surface 525 to form a second L-shaped step. Therefore, the thickness of the first connecting portion 522 is greater than the thickness of each of the first bus portion 521 and the second bus portion 523. A step surface 526 is formed between the second surface 525 of the first connecting portion 522 and the second surface 525 of the second bus portion 523. The step surface 526 and the second bus portion 523 cooperatively define an L-shaped groove. The first extending piece 532 is disposed in the L-shaped groove and spaced apart from the second bus portion 523 to form the first socket 51. The step surface 526 is configured to limit the plugging depth of the connector. In addition, the distance between the first extending piece 532 and the second bus portion 523 is adjustable to change the width of the first socket 51 for matching connectors with different thicknesses.

In some embodiments, the first connecting piece 531 is detachably connected to the first connecting portion 522. The first adapter board 53 further includes a first conductive spacer 533 disposed between the first connecting piece 531 and the first connecting portion 522, which can adjust the gap between the first extending piece 532 and the second bus portion 523 to enhance connection stability. In some embodiments, the first conductive spacer 533 is made of graphite to improve electrical conductivity.

Referring to FIGS. 5, 8 and 9, the second bus board 62 includes a third bus portion 621, a second connecting portion 622, and a fourth bus portion 623 connected to each other in sequence. The third bus portion 621 is connected to the second conductive bar 31. The second adapter board 63 includes a second connecting piece 631 disposed on the housing 1 and a second extending piece 632 disposed on the second connecting piece 631. An end of the second connecting piece 631 away from the second extending piece 632 is connected to the second connecting portion 622. The second extending piece 632 is spaced apart from the fourth bus portion 623 to form the second socket 61. The structure of the second bus board 62 is substantially identical to that of the first bus board 52, and the structure of the second adapter board 63 is substantially identical to that of the first adapter board 53, which will not be elaborated.

In some embodiments, the second connecting piece 631 is detachably connected to the second connecting portion 622. The second adapter board 63 further includes a second conductive spacer 633 disposed between the second connecting piece 631 and the second connecting portion 622, which can adjust the gap between the second extending piece 632 and the fourth bus portion 623 to enhance connection stability. In some embodiments, the second conductive spacer 633 is made of graphite to improve electrical conductivity.

Referring to FIGS. 1, 8, and 9, the insulating sheet 7 is disposed between the first bus bar 5 and the second bus bar 6 to electrically isolate the first bus bar 5 and the second bus bar 6. Thus, the direct current path between the positive pole and the negative pole of the first connector 201 is blocked. In this way, current from the positive pole and negative pole of the power cabinet 400 can only flow through the external loads 500 to form a complete circuit, thereby realizing electrical testing.

In some embodiments, the insulating sheet 7 is sandwiched between the first bus board 52 and the second bus board 62 and extends beyond both boards to enhance insulation performance.

In some embodiments, the insulating sheet 7 is integrally formed with the first bus board 52 and the second bus board 62. The insulating sheet 7 is located between the first connecting portion 522 and the second connecting portion 622, and extends to a position between the second bus portion 523 and the fourth bus portion 623.

In some embodiments, the insulating sheet 7 includes a first insulating surface 71 and a second insulating surface 72 opposite to the first insulating surface 71. A portion of the first insulating surface 71 recessed toward the second insulating surface 72 to form a first mounting groove 73. A portion of the second insulating surface 72 recessed toward the first insulating surface 71 to form a second mounting groove 74. The first connecting portion 522 and the second bus portion 523 are embedded in the first mounting groove 73. The thickness of the second bus portion 523 is equal to the depth of the first mounting groove 74. The second connecting portion 622 and the fourth bus portion 623 are embedded in the second mounting groove 74. The thickness of the fourth bus portion 623 is equal to the depth of the second mounting groove 74. When the positive pole and negative pole of the first connector 201 of the electrical testing fixture 200 are inserted into the first socket 51 and the second socket 61, respectively, sufficient electrical contact area can be ensured.

In some embodiments, the insulating sheet 7 close to each of the first socket 51 and the second socket 61 defines an inclined surface. Thus, the end portion of the insulating sheet 7 is substantially triangular. Thus, the poles of the first connector 201 can be easily inserted into the first socket 51 and the second socket 61, respectively. And reliable electrical isolation is maintained between the first bus bar 5 and the second bus bar 6.

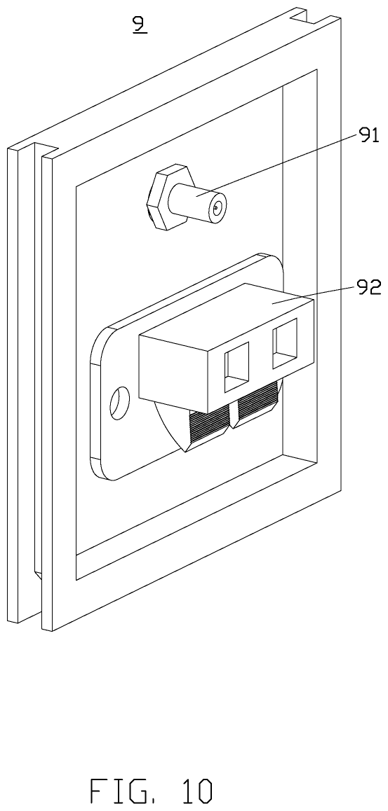

Referring to FIGS. 3 and 10, the connecting fixture 100 further includes an output connector 9 disposed on the housing 1. The output connector 9 is electrically connected to the first conductive bar 21 or the second conductive bar 31. The output connector 9 includes a server message block terminal (that is SMB terminal 91) and a wire clamp base 92. The output connector 9 is used for connecting an oscilloscope to display waveforms during testing.

The connecting fixture 100 of the present disclosure has the following advantages. The first conductive bar 21 can connect the plurality of first terminals 22, and the second conductive bar 31 can connect the plurality of second terminals 32. Thus, the multiple groups of terminals can be rapidly connected to the ports of loads. The first conductive bar 21 and the second conductive bar 31 are further connected to the electrical testing fixture 200 through the bus connector 4. With the connecting fixture 100, the electrical testing fixture 200 can perform rapid testing on a large number of densely arranged server ports. Therefore, the testing process is simple, the testing efficiency is high, manual repeated plugging is reduced, and the measurement accuracy is improved. The bus connector 4 is capable of being plugged with multiple first connectors 201, so various electrical test procedures can be performed without replacing the electrical testing fixture 200, which improves the integration and usability of the electrical testing fixture 200 and the entire electrical testing system 1000. In addition, the electrical testing device 300 is applicable to at least one of current testing and voltage testing for high-power loads. This blind-mating high-current connecting fixture 100 meets the frequent connection and disconnection requirements between the power cabinet 400 and loads 500.

Even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present embodiments to the full extent indicated by the plain meaning of the terms in which the appended claims are expressed.

What is claimed is:

1. A connecting fixture comprising:
a housing comprising a first side wall and a second side wall disposed opposite to the first side wall, the first side wall and the second side wall cooperatively defining a cavity;
a first conductive structure comprising a first conductive bar disposed in the cavity and a plurality of first terminals disposed on a side of the first side wall away from the cavity, each of the plurality of first terminals extending through the first side wall and electrically connected to the first conductive bar;
a second conductive structure comprising a second conductive bar disposed in the cavity and a plurality of second terminals disposed on a side of the second side wall away from the cavity, each of the plurality of second terminals extending through the second side wall and electrically connected to the second conductive bar, wherein each of the plurality of the first terminals and a corresponding one of the plurality of the second terminals are configured to connect two poles of a load, respectively; and
a bus connector disposed at an end of the housing and electrically connected to each of the first conductive bar and the second conductive bar, the bus connector further configured to detachably and electrically connected to an electrical testing fixture.

2. The connecting fixture according to claim 1, wherein the bus connector comprises a first bus bar, a second bus bar, and an insulating sheet, the first bus bar and the second bus bar are arranged side by side, the insulating sheet is disposed between the first bus bar and the second bus bar; the first bus bar is electrically connected to the first conductive bar and comprises a first socket at an end of the first bus bar away from the first conductive bar; the second bus bar is electrically connected to the second conductive bar and comprises a second socket at an end of the second bus bar away from the second conductive bar; the first socket and the second socket are configured to connect the two poles of the load, respectively.

3. The connecting fixture according to claim 2, wherein the first bus bar further comprises a first bus board and a first adapter board, the first bus board is electrically connected to the first conductive bar, the first adapter board is connected to the first bus board, and the first adapter board and the first bus board cooperatively form the first socket;
the second bus bar further comprises a second bus board and a second adapter board, the second bus board is electrically connected to the second conductive bar, the second adapter board is connected to the second bus board, and the second adapter board and the second bus board cooperatively form the second socket.

4. The connecting fixture according to claim 3, wherein the first bus board further comprises a first bus portion, a first connecting portion, and a second bus portion connected to each other in sequence, an end of the first bus portion away from the first connecting portion is connected to the first conductive bar, the first adapter board comprises a first connecting piece disposed on the housing and a first extending piece disposed on the first connecting piece, an end of the first connecting piece away from the first extending piece is connected to the first connecting portion, the first extending piece is disposed opposite to the second bus portion to form the first socket;
the second bus board further comprises a third bus portion, a second connecting portion, and a fourth bus portion connected to each other in sequence, the third bus portion is connected to the second conductive bar, the second adapter board comprises a second connecting piece disposed on the housing and a second extending piece disposed on the second connecting piece, an end of the second connecting piece away from the second extending piece is connected to the second connecting portion, the second extending piece is disposed opposite to the fourth bus portion to form the second socket.

5. The connecting fixture according to claim 4, wherein the first adapter board further comprises a first conductive spacer disposed between the first connecting piece and the first connecting portion, the first conductive spacer is configured to adjust a gap between the first extending piece and the second bus portion;
the second adapter board further comprises a second conductive spacer disposed between the second connecting piece and the second connecting portion, the second conductive spacer is configured to adjust a gap between the second extending piece and the fourth bus portion.

6. The connecting fixture according to claim 5, wherein each of the first conductive spacer and the second conductive spacer is made of graphite.

7. The connecting fixture according to claim 1, wherein the plurality of the first terminals is arranged in an array, the plurality of the second terminals is arranged in an array, a number of the plurality of first terminals is equal to a number of the plurality of second terminals.

8. The connecting fixture according to claim 7, wherein a structure of each of the plurality of first terminals is substantially same as a structure of each of the plurality of second terminals;
each of the plurality of first terminals comprises a first end, a second end, and a fixing portion, the first end and the second end are connected to two opposite ends of the fixed portion, respectively; the first end extends through the first side wall into the cavity and is electrically connected to the first conductive bar, the fixing portion and the second end are disposed on a side of the first side wall away from the cavity, and the second end is configured to connect to the load.

9. The connecting fixture according to claim 8, wherein the first end comprises a connecting rod electrically connected to the second end and a limiting portion sleeved on a segment of the connecting rod close to the fixing portion, an outer diameter of the connecting rod is smaller than an outer diameter of the limiting portion, the connecting rod extends through the first conductive bar, and the limiting portion is disposed between the first conductive bar and the first side wall to separate the first conductive bar and the first side wall from each other.

10. The connecting fixture according to claim 1, further comprising an output connector disposed on the housing, wherein the output connector is electrically connected to the first conductive bar or to the second conductive bar, the output connector comprises a server message block terminal and a wire clamp base.

11. An electrical testing device comprising:
an electrical testing fixture comprising at least one first connector and a second connector; and
a connecting fixture comprising:
a housing comprising a first side wall and a second side wall disposed opposite to the first side wall, the first side wall and the second side wall cooperatively defining a cavity;
a first conductive structure comprising a first conductive bar disposed in the cavity and a plurality of first terminals disposed on a side of the first side wall away from the cavity, each of the plurality of first terminals extending through the first side wall and electrically connected to the first conductive bar;
a second conductive structure comprising a second conductive bar disposed in the cavity and a plurality of second terminals disposed on a side of the second side wall away from the cavity, each of the plurality of second terminals extending through the second side wall and electrically connected to the second conductive bar, wherein each of the plurality of the first terminals and a corresponding one of the plurality of the second terminals are configured to connect two poles of a load, respectively; and
a bus connector disposed at an end of the housing and electrically connected to each of the first conductive bar and the second conductive bar, the bus connector further configured to detachably and electrically connected to an electrical testing fixture,
wherein the at least one first connector is detachably and electrically connected to the bus connector, the second connector is configured to detachably and electrically connected to a power cabinet; each of the plurality of first terminals and a corresponding one of the plurality of second terminals are configured to connect two poles of each of a load, respectively; the electrical testing device is configure to detect at least one of a current and a voltage between the power cabinet and the load.

12. The electrical testing device according to claim 11, wherein the bus connector comprises a first bus bar, a second bus bar, and an insulating sheet, the first bus bar and the second bus bar are arranged side by side, the insulating sheet is disposed between the first bus bar and the second bus bar; the first bus bar is electrically connected to the first conductive bar and comprises a first socket at an end of the first bus bar away from the first conductive bar; the second bus bar is electrically connected to the second conductive bar and comprises a second socket at an end of the second bus bar away from the second conductive bar; the first socket and the second socket are configured to connect the two poles of the load, respectively.

13. The electrical testing device according to claim 12, wherein the first bus bar further comprises a first bus board and a first adapter board, the first bus board is electrically connected to the first conductive bar, the first adapter board is connected to the first bus board, and the first adapter board and the first bus board cooperatively form the first socket;
the second bus bar further comprises a second bus board and a second adapter board, the second bus board is electrically connected to the second conductive bar, the second adapter board is connected to the second bus board, and the second adapter board and the second bus board cooperatively form the second socket.

14. The electrical testing device according to claim 13, wherein the first bus board further comprises a first bus portion, a first connecting portion, and a second bus portion connected to each other in sequence, an end of the first bus portion away from the first connecting portion is connected to the first conductive bar, the first adapter board comprises a first connecting piece disposed on the housing and a first extending piece disposed on the first connecting piece, an end of the first connecting piece away from the first extending piece is connected to the first connecting portion, the first extending piece is disposed opposite to the second bus portion to form the first socket;
the second bus board further comprises a third bus portion, a second connecting portion, and a fourth bus portion connected to each other in sequence, the third bus portion is connected to the second conductive bar, the second adapter board comprises a second connecting piece disposed on the housing and a second extending piece disposed on the second connecting piece, an end of the second connecting piece away from the second extending piece is connected to the second connecting portion, the second extending piece is disposed opposite to the fourth bus portion to form the second socket.

15. The electrical testing device according to claim 14, wherein the first adapter board further comprises a first conductive spacer disposed between the first connecting piece and the first connecting portion, the first conductive spacer is configured to adjust a gap between the first extending piece and the second bus portion;
the second adapter board further comprises a second conductive spacer disposed between the second connecting piece and the second connecting portion, the second conductive spacer is configured to adjust a gap between the second extending piece and the fourth bus portion;
each of the first conductive spacer and the second conductive spacer is made of graphite.

16. The electrical testing device according to claim 11, wherein the plurality of the first terminals is arranged in an array, the plurality of the second terminals is arranged in an array, a number of the plurality of first terminals is equal to a number of the plurality of second terminals.

17. The electrical testing device according to claim 16, wherein a structure of each of the plurality of first terminals is substantially same as a structure of each of the plurality of second terminals;
each of the plurality of first terminals comprises a first end, a second end, and a fixing portion, the first end and the second end are connected to two opposite ends of the fixed portion, respectively; the first end extends through the first side wall into the cavity and is electrically connected to the first conductive bar, the fixing portion and the second end are disposed on a side of the first side wall away from the cavity, and the second end is configured to connect to the load.

18. The electrical testing device according to claim 17, wherein the first end comprises a connecting rod electrically connected to the second end and a limiting portion sleeved on a segment of the connecting rod close to the fixing portion, an outer diameter of the connecting rod is smaller than an outer diameter of the limiting portion, the connecting rod extends through the first conductive bar, and the limiting portion is disposed between the first conductive bar and the first side wall to separate the first conductive bar and the first side wall from each other.

19. The electrical testing device according to claim 11, further comprising an output connector disposed on the housing, wherein the output connector is electrically connected to the first conductive bar or the second conductive bar, the output connector comprises a server message block terminal and a wire clamp base.

20. The electrical testing device according to claim 11, wherein the at least one first connector comprises a plurality of first connectors arranged in a column along a vertical direction.
